(19) United States
(12) Patent Application Publication
(10) Pub. No.: US 2026/0173656 A1
(43) Pub. Date: Jun. 18, 2026

(54) DISPLAY MODULE, METHOD FOR MANUFACTURING THE SAME, AND ELECTRONIC DEVICE

(71) Applicant: SAMSUNG DISPLAY CO., LTD., YONGIN-SI (KR)

(72) Inventors: Changsuk Lee, YONGIN-SI (KR); Taesung Kim, YONGIN-SI (KR); Daewon Choi, YONGIN-SI (KR)

(21) Appl. No.: 19/215,581

(22) Filed: May 22, 2025

(30) Foreign Application Priority Data
Dec. 17, 2024 (KR) 10-2024-0188865

(51) Int. Cl. H10K 59/122; H10K 59/12; H10K 59/131; H10K 59/80

(52) U.S. Cl. CPC H10K 59/122; H10K 59/1201; H10K 59/131; H10K 59/873

(57) ABSTRACT

A method of manufacturing a display module includes forming first and second pixel electrodes disposed on a same layer on a substrate; forming a pixel defining layer on the substrate and covering the first and second pixel electrodes; forming a first metal layer on the pixel defining layer and a second metal layer on the first metal layer; forming initial conductive structures including portions of the first and second metal layers and forming a first opening exposing a portion of the pixel defining layer between the initial conductive structures upwardly; forming a third metal layer covering upper surfaces and outer side surfaces of the initial conductive structures and a portion of the pixel defining layer exposed through the first opening; and forming a second opening in the third metal layer to expose, in an upward direction, at least a portion of upper surfaces of each of the initial conductive structures.

### CROSS-REFERENCE TO RELATED APPLICATION

This application claims priority under 35 U.S.C. § 119 to Korean Patent Application No. 10-2024-0188865, filed on Dec. 17, 2024 in the Korean Intellectual Property Office, the present disclosure of which is incorporated by reference in its entirety herein.

### 1. Technical Field

One or more embodiments relate to a display module, a method of manufacturing the same, and an electronic device, and more particularly, to a display module with a reduced defect rate, a method of manufacturing the same, and an electronic device.

### 2. Discussion of Related Art

A display module may receive image information and display images to a user. The display module may be used as a display portion of various electronic devices, including small electronic devices, such as mobile phones, or larger electronic devices, such as televisions.

The display module includes a plurality of pixels that emit light by receiving electrical signals to display images externally to the user. Each pixel includes a light emitting element. When the light emitting element is an organic light emitting display device, the display device may include an organic light emitting diode (OLED) as the light emitting element. Generally, the display module may include a thin film transistor (TFT) and an OLED disposed on a substrate.

Various types of electronic devices may provide visual interfaces to users through the display module.

### SUMMARY

One or more embodiments include a display module with a reduced defect rate, a method of manufacturing the same, and an electronic device. However, this objective is just an example and does not limit the scope of embodiments of the present disclosure.

Additional aspects will be set forth in part in the description which follows and, in part, will be apparent from the description, or may be learned by practice of the presented embodiments of the present disclosure.

According to an embodiment of the present disclosure, a method of manufacturing a display module includes forming a first pixel electrode and a second pixel electrode disposed on a same layer as each other on a substrate. A pixel defining layer is formed on the substrate and covers the first pixel electrode and the second pixel electrode. A first metal layer is formed on the pixel defining layer and a second metal layer is formed on the first metal layer. Initial conductive structures are formed comprising a portion of the first metal layer and a portion of the second metal layer by performing a first etching process on the first metal layer and the second metal layer. A portion of the pixel defining layer is exposed between the initial conductive structures by the first etching process. A third metal layer is formed covering upper surfaces and outer side surfaces of the initial conductive structures and the portion of the pixel defining layer exposed between the initial conductive structures. A second etching process is performed on the third metal layer to expose, in an upward direction, at least a central region of an upper surface of the portion of the second metal layer.

In an embodiment, the method may further include forming a conductive structure by removing a portion of the second metal layer.

In an embodiment, the conductive structure may have a recess space formed in a space where the portion of the second metal layer is removed.

In an embodiment, the conductive structure may include a portion of the first metal layer as a bottom layer including a conductive material and disposed on the pixel defining layer, and a portion of the third metal layer as a protrusion surrounding an outer side surface of the portion of the first metal layer and protruding upward in a cross-sectional view.

In an embodiment, the first metal layer and the third metal layer may include a first conductive material, and the second metal layer may include a second conductive material. An etching selectivity of the second conductive material may be greater than an etching selectivity of the first conductive material.

In an embodiment, a first end of a portion of the third metal layer may directly contact an outer side surface of the portion of the first metal layer and an upper surface of the pixel defining layer, and a second end of the portion of the third metal layer may be a protrusion lip protruding towards an inner direction of the conductive structure.

In an embodiment, the method may further include removing a portion of the pixel defining layer to expose at least a central region of the first pixel electrode and at least a central region of the second pixel electrode upwardly.

According to an embodiment, the method of manufacturing a display module may further include forming a first intermediate layer covering the conductive structures, at least the central region of the first pixel electrode, at least the central region of the second pixel electrode, and the pixel defining layer, and forming a first counter electrode covering the first intermediate layer and directly contacting the conductive structure.

In an embodiment, the first intermediate layer may cover an upper surface and a side surface of the protrusion lip, and the first counter electrode may directly contact a lower end of the side surface of the protrusion lip.

According to an embodiment of the present disclosure, a display module includes a substrate. A first pixel electrode and a second pixel electrode are disposed on the substrate. A pixel defining layer is disposed on the substrate and covers edges of each of the first pixel electrode and the second pixel electrode and exposes a central portion of upper surfaces of the first pixel electrode and the second pixel electrode to define a first emission region and a second emission region, respectively. A conductive structure is disposed between the first pixel electrode and the second pixel electrode on the pixel defining layer. A first intermediate layer covers the first emission region and a first side of the conductive structure. A second intermediate layer covers the second emission region and a second side of the conductive structure. A first counter electrode covers the first intermediate layer and directly contacts the conductive structure. A second counter electrode covers the second intermediate layer and directly contacts the conductive structure.

In an embodiment, the conductive structure may include a bottom layer including a conductive material and disposed on the pixel defining layer, and a protrusion including the conductive material and protruding upward with respect to the pixel defining layer.

In an embodiment, a first end of the protrusion may directly contact an outer side surface of the bottom layer and an upper surface of the pixel defining layer, and a second end of the protrusion may be a protrusion lip protruding towards an inner direction of the conductive structure.

In an embodiment, the first counter electrode may directly contact a side surface of the protrusion lip.

In an embodiment, the first intermediate layer may cover an upper surface and an inner side surface of the protrusion lip, and the first counter electrode may directly contact a lower end of the inner side surface of the protrusion lip.

In an embodiment, the bottom layer and the protrusion may define a recess space of the conductive structure.

In an embodiment, the display module may further include a first encapsulation layer sealing the first intermediate layer and the first counter electrode.

In an embodiment, the first encapsulation layer may fill a portion of the recess space.

In an embodiment, the first encapsulation layer may be spaced apart from an upper surface of the bottom layer.

In an embodiment, the display module may further include a second encapsulation layer covering the first encapsulation layer and having a portion disposed between the first encapsulation layer and the bottom layer.

According to an embodiment of the present disclosure, an electronic device includes a memory storing data information. A processor generates data signals and/or control signals based on the data information. A display module operates based on the data signals and/or control signals. The display module comprises a substrate. A first pixel electrode and a second pixel electrode are disposed on the substrate. A pixel defining layer is disposed on the substrate and covers edges of each of the first pixel electrode and the second pixel electrode and exposes a central portion of upper surfaces of the first pixel electrode and the second pixel electrode to define a first emission region and a second emission region, respectively. A conductive structure is disposed between the first pixel electrode and the second pixel electrode on the pixel defining layer. A first intermediate layer covers the first emission region and a portion of the conductive structure. A second intermediate layer covers the second emission region and a portion of the conductive structure. A first counter electrode covers the first intermediate layer and directly contacts the conductive structure. A second counter electrode covers the second intermediate layer and directly contacts the conductive structure.

### BRIEF DESCRIPTION OF THE DRAWINGS

The above and other aspects, features, and advantages of certain non-limiting

embodiments of the present disclosure will be more apparent from the following description taken in conjunction with the accompanying drawings, in which:

FIG. 1 is a plan view schematically illustrating a display module included in a display device according to an embodiment of the present disclosure;

FIG. 2 is an example equivalent circuit diagram schematically illustrating a sub-pixel of the display device of FIG. 1 according to an embodiment of the present disclosure;

FIG. 3 is a cross-sectional view schematically illustrating a cross-section of a display region and a peripheral region of FIG. 1 according to an embodiment of the present disclosure;

FIG. 4 is a plan view schematically illustrating region A of the display region of FIG. 1 according to an embodiment of the present disclosure;

FIG. 5 is an example schematic cross-sectional view obtained along line I-I′ of FIG. 4 according to an embodiment of the present disclosure;

FIGS. 6 to 17 are cross-sectional views illustrating cross-sections of a display module according to a method of manufacturing the display module, according to embodiments of the present disclosure;

FIG. 18 is a block diagram of an electronic device according to an embodiment of the present disclosure; and

FIG. 19 is a schematic diagram of electronic devices according to various embodiments of the present disclosure.

### DETAILED DESCRIPTION OF EMBODIMENTS

Reference will now be made in detail to non-limiting embodiments, examples of which are illustrated in the accompanying drawings, wherein like reference numerals refer to like elements throughout. In this regard, the described embodiments may have different forms and should not be construed as being limited to the descriptions set forth herein. Accordingly, non-limiting embodiments are merely described below, by referring to the figures, to explain aspects of the present description. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

The described embodiments may have various modifications and several embodiments, and non-limiting embodiments are illustrated in the drawings and described in detail in the detailed description. Effects and features of embodiments and methods for achieving them will become more apparent from embodiments described below with reference to the drawings. However, embodiments of the present disclosure are not necessarily limited to the described embodiments but may be implemented in various forms.

Below, embodiments will be described in detail with reference to the accompanying drawings, and when describing with reference to the drawings, the same or corresponding components are denoted by the same reference numerals and redundant descriptions thereof will be omitted.

In the following embodiments, terms such as first, second, etc. are used for the purpose of distinguishing one component from another component rather than having limiting meanings. Also, in the following embodiments, singular expressions include plural expressions unless the context clearly indicates otherwise.

In the following embodiments, when various components such as a layer, film, region, plate, etc., are described as being “on” another component, this includes not only cases where the components are “directly on” each other but also cases where other components are interposed therebetween. When various components such as a layer, film, region, plate, etc., are described as being “directly on” another component, no intervening components may be interposed therebetween.

Also, for convenience of description, the sizes of components may be exaggerated or reduced in the drawings. For example, the size and thickness of each component shown in the drawings may be arbitrarily shown for convenience of description, and embodiments are not necessarily limited to what is illustrated.

In the following embodiments, terms such as “include” or “have” mean that features or components described in the specification exist, and do not preclude the possibility that one or more other features or components may be added.

In the following embodiments, when a portion of a film, region, component, etc., is described as being above or on another portion, this includes not only cases where the portion is directly above the other portion but also cases where other films, regions, components, etc., are interposed therebetween.

When an embodiment may be implemented differently, a specific process order may be performed differently from the described order. For example, two processes described sequentially may be performed substantially simultaneously or in reverse order from the described sequence.

In the present specification, “A and/or B” indicates cases where it is A, B, or both A and B. And, “at least one of A and B” indicates cases where it is A, B, or both A and B.

In the following embodiments, when films, regions, components, etc., are described as being connected, this includes cases where they are directly connected, and/or cases where they are indirectly connected with other films, regions, components, etc., interposed therebetween. For example, in the present specification, when films, regions, components, etc., are described as being electrically connected, this indicates cases where they are directly electrically connected, and/or cases where they are indirectly electrically connected with other films, regions, components, etc., interposed therebetween.

In the following embodiments, x-axis, y-axis, and z-axis may be interpreted in a broad sense including but not limited to three axes in an orthogonal coordinate system. For example, the x-axis, y-axis, and z-axis may be orthogonal to each other, or may refer to different directions that are not orthogonal to each other.

Below, based on the above-described contents, a display module and a method for manufacturing the same according to an embodiment will be described in detail as follows.

The present disclosure concerns a display module and method for manufacturing same in which counter electrodes and intermediate layers are separated from each other by a conductive structure that includes a protrusion having a protrusion lip. For example, the counter electrode may be distinguished to correspond to each of the emission regions. A counter electrode may cover one intermediate layer and may extend over one pixel electrode having an exposed surface forming the emission region. The counter electrode directly contacts two conductive structures on opposite sides of the emission region. Using multiple conductive structures multiple counter electrodes may be electrically connected to each other. Through the structure, reliability of electrical connection between counter electrodes may be increased, and interference between pixels may be effectively prevented. The display module and method of manufacture reduces a defect rate.

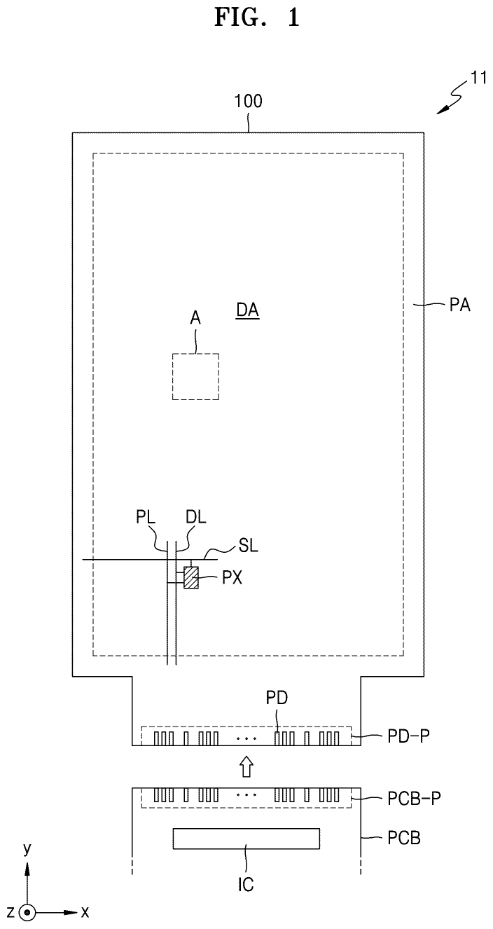

FIG. 1 is a plan view schematically illustrating a display module included in a display device according to an embodiment.

As illustrated in FIG. 1, the display module 11 includes a display region DA and a peripheral region PA disposed outside the display region DA (e.g., in a plan view). In FIG. 1, while the display region DA is illustrated as having a rectangular shape (e.g., in a plan view), embodiments of the present disclosure are not necessarily limited to the rectangular shape of the display region. The display region DA may have various shapes such as, for example, circular, elliptical, polygonal, or specific geometrical shapes (e.g., in a plan view).

The display region DA is a portion for displaying images, where a plurality of sub-pixels PX may be disposed. Each sub-pixel PX may include a display element such as an organic light emitting diode. In an embodiment, each sub-pixel PX may, for example, emit red, green, or blue light. Such sub-pixels PX may be connected to pixel circuits including thin film transistors (TFT), storage capacitors, and the like. Such pixel circuits may be connected to scan lines SL for transmitting scan signals, data lines DL crossing the scan lines SL for transmitting data signals, and driving voltage lines PL for supplying driving voltages. For example, the data lines DL and driving voltage lines PL may extend in a y-axis direction (hereinafter, referred to as a first direction), and the scan lines SL may extend in an x-axis direction (hereinafter, referred to as a second direction).

The sub-pixels PX may emit light having luminance corresponding to electrical signals received from the data lines DL. The display region DA may display predetermined images through light emitted from the sub-pixels PX. For reference, the sub-pixel PX may be defined as an emission region that emits light of one color among red, green, and blue colors.

The peripheral region PA is a region where sub-pixels PX are not disposed and may be a region that does not display images. Power supply wirings for driving the sub-pixels PX and the like may be disposed in the peripheral region PA. Additionally, pads PD may be disposed in the peripheral region PA, and the peripheral region PA may include a pad region PD-P where the pads PD are disposed.

An integrated circuit (IC) such as a driver IC may be mounted on a printed circuit board (PCB) including driving circuits, and terminals electrically connected to the IC may be disposed in a terminal region PCB-P of the PCB. The terminal region PCB-P corresponds to the pad region PD-P, and the above-mentioned pads PD may be electrically connected to terminals of the terminal region PCB-P in the peripheral region PA.

For reference, since the display module 11 includes a substrate 100, the substrate 100 may have the display region DA and peripheral region PA. Detailed description of the substrate 100 will be described below.

Also, a plurality of transistors may be disposed in the display region DA. For the plurality of transistors, depending on the type of transistor (N-type or P-type) and/or operating conditions, a first terminal of the transistor may be a source electrode or a drain electrode, and a second terminal may be the other electrode among the source electrode and the drain electrode different from the first terminal. For example, in an embodiment in which the first terminal is the source electrode, the second terminal may be the drain electrode.

Below, while an organic light emitting display device is described as an example of a display device according to an embodiment, the display device is not necessarily limited to the organic light emitting display device. In an embodiment, the display device may be an inorganic light emitting display device or a quantum dot light emitting display device. For example, the emission layer included in the display device may include organic materials or inorganic materials. In some cases, the display device may include an emission layer and quantum dots disposed on a path of light emitted from the emission layer.

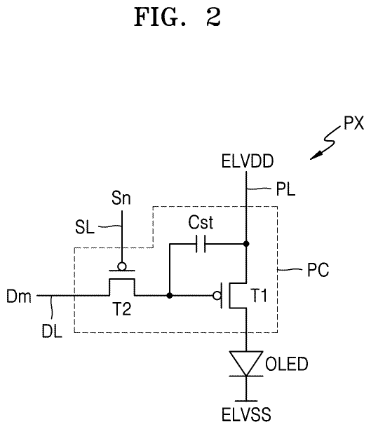

FIG. 2 is an equivalent circuit diagram schematically illustrating a sub-pixel of the display device of FIG. 1.

The equivalent circuit diagram of FIG. 2 is a basic equivalent circuit diagram, and at least one of various modified equivalent circuit diagrams applying the equivalent circuit diagram of FIG. 2 may be applied to the display module according to an embodiment.

While a pMOS type thin film transistor is illustrated in FIG. 2 for convenience of description, the pixel circuit mentioned in the present specification is not necessarily limited to the pMOS type thin film transistor and may be modified in various ways.

As illustrated in FIG. 2, each sub-pixel PX may include a pixel circuit PC connected to a scan line SL and a data line DL, and a light emitting element OLED connected to the pixel circuit PC.

For example, in an embodiment the pixel circuit PC may include a first thin film transistor T1, a second thin film transistor T2, and a storage capacitor Cst. The second thin film transistor T2 may be connected to the scan line SL and the data line DL, and may transmit a data signal Dm input through the data line DL to the first thin film transistor T1 according to a scan signal Sn input through the scan line SL.

For example, the first thin film transistor T1 may be a driving thin film transistor, and the second thin film transistor T2 may be a switching thin film transistor.

For example, the storage capacitor Cst may be connected to the second thin film transistor T2 and the driving voltage line PL, and may store a voltage corresponding to a difference between a voltage received from the second thin film transistor T2 and a first power voltage ELVDD (e.g., a driving voltage) supplied to the driving voltage line PL.

For example, in an embodiment the first thin film transistor T1 may be connected to the driving voltage line PL and the storage capacitor Cst, and may control a driving current flowing through the light emitting element OLED from the driving voltage line PL in correspondence to the voltage value stored in the storage capacitor Cst. The light emitting element OLED may emit light having predetermined luminance by the driving current.

The light emitting element OLED may receive a second power voltage ELVSS (e.g., a common voltage). For example, the light emitting element OLED may receive the second power voltage ELVSS (e.g., a common voltage) through a counter electrode (e.g., a cathode), and the light emitting element OLED may emit light having predetermined luminance by a driving current corresponding to a voltage difference between the first power voltage ELVDD (e.g., the driving voltage) and the second power voltage ELVSS (e.g., the common voltage).

While FIG. 2 describes an embodiment in which the pixel circuit PC includes two thin film transistors and one storage capacitor Cst, embodiments of the present disclosure are not necessarily limited to the number of thin film transistors and storage capacitors. For example, the pixel circuit PC may include not only two or more capacitors but also three or more thin film transistors.

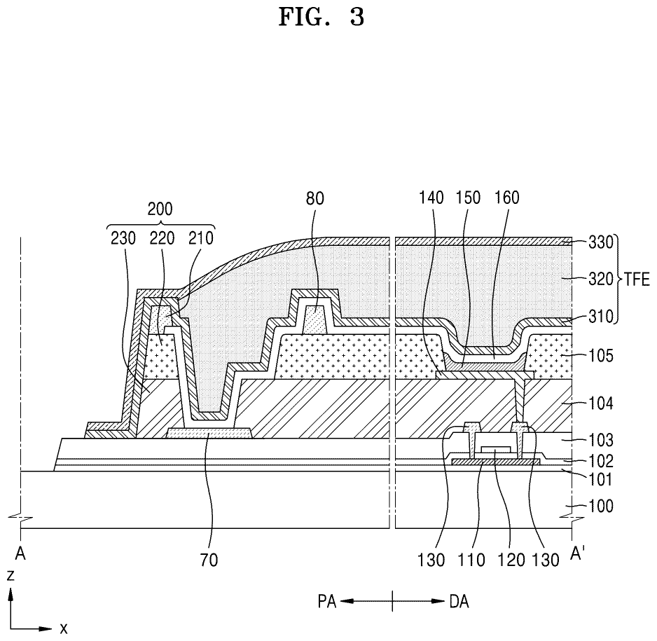

FIG. 3 is a cross-sectional view schematically illustrating a cross-section obtained from the display region and the peripheral region of FIG. 1.

The substrate 100 may include regions corresponding to the display region DA and the peripheral region PA outside the display region DA (e.g., in a plan view) as described above. The substrate 100 may include various materials having flexible or bendable characteristics.

For example, in an embodiment the substrate 100 may include glass, metal, or polymer resin. Also, the substrate 100 may include polymer resins such as polyethersulfone, polyacrylate, polyetherimide, polyethylene naphthalate, polyethylene terephthalate, polyphenylene sulfide, polyarylate, polyimide, polycarbonate, or cellulose acetate propionate.

For example, the substrate 100 may have a multilayer structure including two layers each comprising such polymer resins and a barrier layer comprising inorganic materials (e.g., silicon oxide, silicon nitride, silicon oxynitride, etc.) interposed between those layers. Alternatively, the substrate 100 may include inorganic materials such as silicon oxide, silicon nitride, silicon oxynitride, and various layers and components for displaying images (e.g., display elements using organic light emission, display elements using Liquid Crystal, etc.) may be disposed on the substrate 100 including inorganic materials.

A buffer layer 101 may be disposed on the substrate 100 (e.g., disposed directly thereon in the z-axis direction). The buffer layer 101 may serve as a barrier layer and/or blocking layer for preventing diffusion of impurity ions, preventing penetration of moisture or external air, and planarizing the surface. The buffer layer 101 may include silicon oxide, silicon nitride, or silicon oxynitride. Additionally, the buffer layer 101 may control the rate of heat supply during a crystallization process for forming the semiconductor layer 110, enabling uniform crystallization of the semiconductor layer 110.

The semiconductor layer 110 may be disposed on the buffer layer 101 (e.g., disposed directly thereon in the z-axis direction). The semiconductor layer 110 may be made of polysilicon and may include a channel region where impurities are not doped, and source and drain regions formed by doping impurities on both sides of the channel region. The impurities may vary depending on the type of thin film transistor, and may be N-type impurities or P-type impurities.

A gate insulating layer 102 may be disposed on (e.g., disposed directly thereon) the semiconductor layer 110. The gate insulating layer 102 may be provide insulation between the semiconductor layer 110 and a gate layer 120. In an embodiment, the gate insulating layer 102 may include inorganic materials such as silicon oxide, silicon nitride, and/or silicon oxynitride, and may be interposed between the semiconductor layer 110 and the gate layer 120 (e.g., in the z-axis direction). Additionally, the gate insulating layer 102 may have a formation corresponding to the entire surface of the substrate 100, and may have a structure with contact holes formed in predetermined portions. Thus, the insulating layer including inorganic materials may be formed through Chemical Vapor Deposition (CVD) or Atomic Layer Deposition (ALD). The formation of insulating layers through Chemical Vapor Deposition (CVD) or Atomic Layer Deposition (ALD) applies to the embodiments and their variations described below.

The gate layer 120 may be disposed on the gate insulating layer 102 (e.g., disposed directly thereon in the z-axis direction). In an embodiment, the gate layer 120 may be disposed in a position vertically overlapping with the semiconductor layer 110, and may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

An interlayer insulating layer 103 may be disposed on (e.g., disposed directly thereon) the gate layer 120. The interlayer insulating layer 103 may cover the gate layer 120. The interlayer insulating layer 103 may be made of inorganic materials. For example, in an embodiment the interlayer insulating layer 103 may be a metal oxide or metal nitride, and specifically, the inorganic material may include silicon oxide (SiO₂), silicon nitride (SiNx), silicon oxynitride (SiON), aluminum oxide (Al2O₃), titanium oxide (TiO₂), tantalum oxide (Ta2O₅), hafnium oxide (HfO₂), or zirconium oxide (ZrO₂). In some embodiments, the interlayer insulating layer 103 may have a double-layer structure of SiOx/SiNy or SiNx/SiOy.

A conductive layer 130 may be disposed on the interlayer insulating layer 103 (e.g., disposed directly thereon in the z-axis direction). The conductive layer 130 may serve as an electrode connected to source/drain regions of the semiconductor layer through a through hole included in the interlayer insulating layer 103. In an embodiment, the conductive layer 130 may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the conductive layer 130 may include a Ti layer, an Al layer, and/or a Cu layer.

An organic insulating layer 104 may be disposed on the conductive layer 130 (e.g., disposed directly thereon in the z-axis direction). The organic insulating layer 104 may be an organic insulating layer serving as a planarization layer, covering the upper portion of the conductive layer 130 and having a substantially planar upper surface. In an embodiment, the organic insulating layer 104 may include organic materials such as acryl, Benzocyclobutene (BCB), or hexamethyldisiloxane (HMDSO). The organic insulating layer 104 may have various modifications and may be configured as a single layer or multiple layers.

Additionally, in an embodiment, additional conductive layers and additional insulating layers may be interposed between the conductive layer and the pixel electrode, and may be applied to various embodiments. The additional conductive layer may include the same material as the above-described conductive layer and may have the same layer structure. Of course, the additional insulating layer may include the same material as the above-described organic insulating layer and may have the same layer structure.

A pixel electrode 140 may be disposed on the organic insulating layer 104 (e.g., disposed directly thereon in the z-axis direction). In an embodiment, the pixel electrode 140 may be connected to the conductive layer 130 through a contact hole formed in the organic insulating layer 104. A display element may be disposed on the pixel electrode 140. In an embodiment, an organic light emitting diode may be used as the display element. For example, the organic light emitting diode may be interposed on the pixel electrode 140. In an embodiment, the pixel electrode 140 may include a transparent conductive layer formed of transparent conductive oxide such as ITO, In2O3, or IZO, and a reflective layer formed of metal such as Al or Ag. For example, the pixel electrode 140 may have a three-layer structure of ITO/Ag/ITO.

A pixel defining layer 105 may be disposed on the organic insulating layer 104 (e.g., disposed directly thereon in the z-axis direction) and disposed to cover edges of the pixel electrode 140. For example, the pixel defining layer 105 may cover the edges of the pixel electrode 140. The pixel defining layer 105 may have an opening corresponding to the pixel PX, and the opening may be formed to expose at least a central portion of the pixel electrode 140. In an embodiment, the pixel defining layer 105 may include organic materials such as polyimide or hexamethyldisiloxane (HMDSO). Additionally, a spacer 80 may be disposed on the pixel defining layer 105 (e.g., disposed directly thereon in the z-axis direction).

While the spacer 80 is shown to be disposed on the peripheral region PA, the spacer 80 may also be disposed on the display region DA in some embodiments. The spacer 80 may prevent damage to the organic light emitting diode caused by sagging of a mask in a manufacturing process using the mask. In an embodiment, the spacer 80 may include organic insulating material and may be formed as a single layer or multiple layers.

An intermediate layer 150 and a counter electrode 160 may be disposed on the opening of the pixel defining layer 105. The intermediate layer 150 may include low molecular weight or high molecular weight materials, and in an embodiment in which the intermediate layer 150 includes low molecular weight materials, the intermediate layer 150 may include a Hole Injection Layer, a Hole Transport Layer, an Emission Layer, an Electron Transport Layer, and/or an Electron Injection Layer. In an embodiment in which the intermediate layer 150 includes high molecular weight materials, the intermediate layer 150 may typically have a structure including a hole transport layer and an emission layer.

The counter electrode 160 may include a transparent conductive layer formed of transparent conductive oxide such as ITO, In₂O₃, or IZO. The pixel electrode 140 may be used as an anode, and the counter electrode 160 may be used as a cathode. However, in some embodiments the polarity of the electrodes may be applied in reverse.

The structure of the intermediate layer 150 is not necessarily limited to what is described above and may have various structures. For example, at least one of the layers constituting the intermediate layer 150 may be formed integrally with the counter electrode 160. In an embodiment, the intermediate layer 150 may include a patterned layer corresponding to each of multiple pixel electrodes 140.

For example, in an embodiment the counter electrode 160 may be disposed on the upper portion of the display region DA and may be disposed on the entire surface of the display region DA (e.g., commonly disposed). However, as described below, the counter electrode 160 in an embodiment may be distinguished to correspond to each of the emission regions.

The counter electrode 160 may be electrically contacted with a common power supply line 70 disposed in the peripheral region PA. In an embodiment, the counter electrode 160 may extend to directly contact a blocking wall 200. A thin film encapsulation layer TFE may cover the entire display region DA and may be disposed to extend towards and cover at least a portion of the peripheral region PA.

The thin film encapsulation layer TFE may extend to the outside of the common power supply line 70. In an embodiment, the thin film encapsulation layer TFE may include a first encapsulation layer 310, a second encapsulation layer 320, and a third encapsulation layer 330, and the second encapsulation layer 320 may be interposed between the first encapsulation layer 310 and the third encapsulation layer 330 (e.g., in the z-axis direction).

For example, the first encapsulation layer 310 and the third encapsulation layer 330 may be inorganic encapsulation layers. In an embodiment, the first encapsulation layer 310 and the third encapsulation layer 330 may include one or more inorganic materials selected from aluminum oxide, titanium oxide, tantalum oxide, hafnium oxide, zinc oxide, silicon oxide, silicon nitride, and silicon oxynitride.

The first encapsulation layer 310 and the third encapsulation layer 330 may be a single layer or multiple layers including the above-mentioned materials. The first encapsulation layer 310 and the third encapsulation layer 330 may include the same materials or different materials from each other. In an embodiment, the thicknesses of the first encapsulation layer 310 and the third encapsulation layer 330 may be different from each other. The thickness of the first encapsulation layer 310 may be greater than the thickness of the third encapsulation layer 330. Alternatively, the thickness of the third encapsulation layer 330 may be greater than the thickness of the first encapsulation layer 310, or the thicknesses of the first encapsulation layer 310 and the third encapsulation layer 330 may be equal to each other.

For example, the second encapsulation layer may be an organic encapsulation layer. The second encapsulation layer 320 may be referred to as the organic encapsulation layer. The second encapsulation layer 320 may include monomer-based materials or polymer-based materials. The polymer-based materials may include acrylic resin, epoxy resin, polyimide, and polyethylene. In an embodiment, the second encapsulation layer 320 may include acrylate.

A blocking wall 200 may be disposed on the peripheral region PA of the substrate 100. In an embodiment, the blocking wall 200 may include a three-layer structure comprising a portion 230 of the organic insulating layer 104, a portion 220 of the pixel defining layer 105, and a portion 210 of the spacer 80, but is not necessarily limited to the three-layer structure. For example, in an embodiment the blocking wall may have a two-layer structure including two layers among the portion 230 of the organic insulating layer 104, the portion 220 of the pixel defining layer 105, and the portion 210 of the spacer 80, and embodiments of layers constituting the spacer 80 may be variously modified.

The blocking wall 200 may be disposed to surround the display region DA (e.g., in a plan view) and may prevent overflow of the organic encapsulation layer 320 of the thin film encapsulation layer TFE towards the outside of the substrate 100. Therefore, the organic encapsulation layer 320 may contact an inner side surface of the blocking wall 200 facing the display region DA. When describing that the organic encapsulation layer 320 contacts the inner side surface of the blocking wall 200, the contact relationship may be understood that the first encapsulation layer 310 is disposed between the organic encapsulation layer 320 and the blocking wall 200, and the second encapsulation layer 320 directly contacts the first encapsulation layer 310.

The first encapsulation layer 310 and the third encapsulation layer 330 may be disposed on the blocking wall 200 and may extend towards the edge of the substrate 100. However, in some cases, multiple blocking walls 200 may be included.

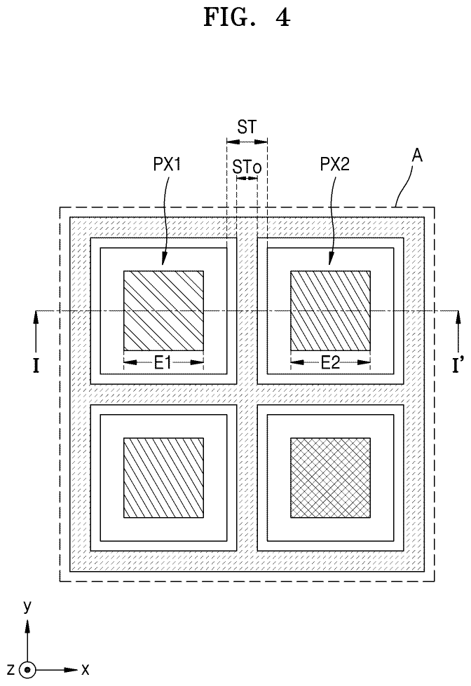

FIG. 4 is a plan view schematically illustrating region A of the display region of FIG. 1.

For reference, among the contents illustrated in FIG. 4, contents that are identical or overlapping with the above-described contents may be omitted.

As illustrated in FIG. 4, a first sub-pixel PX1 and a second sub-pixel PX2 may be adjacent sub-pixels. A first emission region E1 may refer to an emission region that emits light of a first wavelength band. A second emission region E2 may refer to an emission region that emits light of a second wavelength band.

In the plan view, a structure disposition region ST may be disposed between the first emission region E1 and the second emission region E2 (e.g., in the x-axis direction), and a structure recess region STo may be disposed in the center of the structure disposition region. For example, the structure disposition region ST may surround emission regions including the first emission region E1 and the second emission region E2 in the plan view. Since the structure recess region STo is disposed in the center of the structure disposition region ST, the structure recess region STo may also surround emission regions including the first emission region E1 and the second emission region E2 in the plan view.

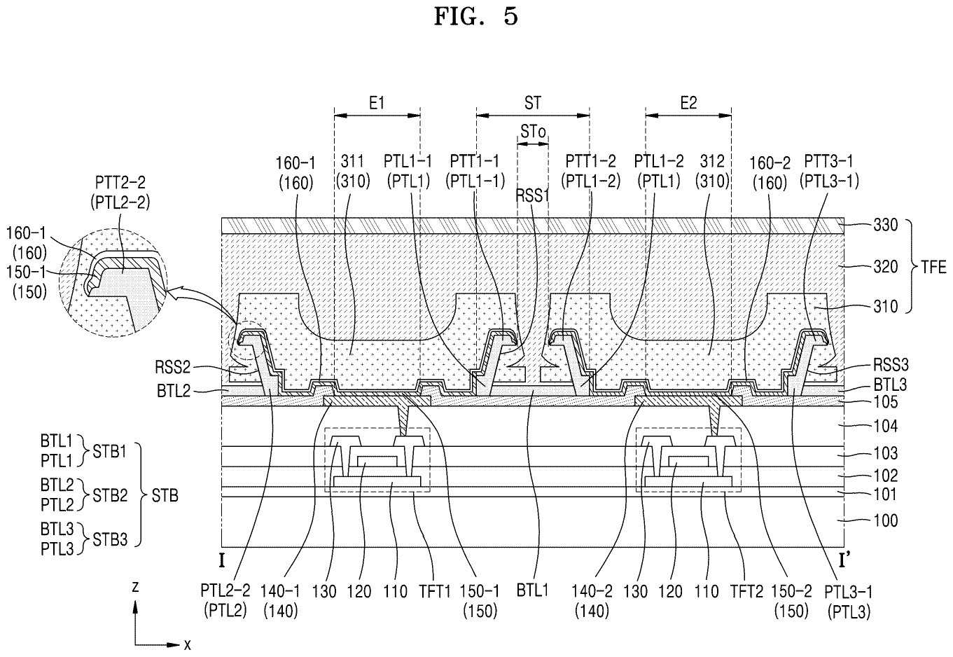

FIG. 5 may be a schematic cross-sectional view obtained along line I-I′ of FIG. 4. For reference, among the descriptions of FIG. 5, contents that are identical or overlapping with the descriptions of FIGS. 1 to 4 may be omitted.

As illustrated in FIG. 5, according to an embodiment, the display module 11 may include the substrate 100, a first pixel electrode 140-1 and a second pixel electrode 140-2 disposed on the substrate 100, the pixel defining layer 105 covering edges of each of the first pixel electrode 140-1 and the second pixel electrode 140-2, and a conductive structure STB disposed between the first pixel electrode 140-1 and the second pixel electrode 140-2 on the pixel defining layer 105. For reference, the conductive structure STB mentioned in the apparatus category may be the same component as the conductive structure mentioned in the method category.

For convenience of description, while only the first pixel electrode 140-1, the second pixel electrode 140-2, the first thin film transistor TFT1, and the second thin film transistor TFT2 are illustrated in FIG. 5, the configuration of the display module apparently may include other pixel electrodes and other thin film transistors disposed on the substrate 100.

For example, a first intermediate layer 150-1 may be disposed on the pixel defining layer 105 (e.g., in the z-axis direction) and may be disposed on a region of the first pixel electrode 140-1 not covered by the pixel defining layer 105. For example, the first intermediate layer 150-1 may be disposed on a region corresponding to the first emission region E1 of the first pixel electrode and may be disposed on a region of the pixel defining layer 105 not covered by the conductive structure STB. The first intermediate layer 150-1 may cover one side (e.g., a lateral side in a plan view, such as in the x-axis direction) of the conductive structure STB. One side of the conductive structure STB may refer to a portion of the conductive structure STB close to the first emission region E1.

For example, a second intermediate layer 150-2 may be disposed on the pixel defining layer 105 and may be disposed on a region of the second pixel electrode 140-2 not covered by the pixel defining layer 105. For example, the second intermediate layer 150-2 may be disposed on a region corresponding to the second emission region E2 of the second pixel electrode 140-2 and may be disposed on a region of the pixel defining layer 105 not covered by the conductive structure STB. The second intermediate layer 150-2 may cover another side (e.g., a lateral side in a plan view, such as in the x-axis direction) of the conductive structure STB. One side of the conductive structure STB may refer to a portion of the conductive structure STB close to the second emission region E2.

A first counter electrode 160-1 may be disposed on the first intermediate layer 150-1 (e.g., in the z-axis direction). The first counter electrode 160-1 may cover an upper surface and side surfaces of the first intermediate layer 150-1. For example, the first counter electrode 160-1 may cover the first intermediate layer 150-1 and may directly contact the conductive structure STB. The first counter electrode 160-1 may be electrically connected to the second counter electrode 160-2 through the conductive structure STB.

The second counter electrode 160-2 may be disposed on the second intermediate layer 150-2 (e.g., in the z-axis direction). The second counter electrode 160-2 may cover an upper surface and side surfaces of the second intermediate layer 150-2. For example, the second counter electrode 160-2 may cover the second intermediate layer 150-2 and may directly contact the conductive structure STB. Using multiple conductive structures STB, multiple counter electrodes may be electrically connected. Through the structure, reliability of electrical connection between counter electrodes may be increased, and interference between pixels may be effectively prevented.

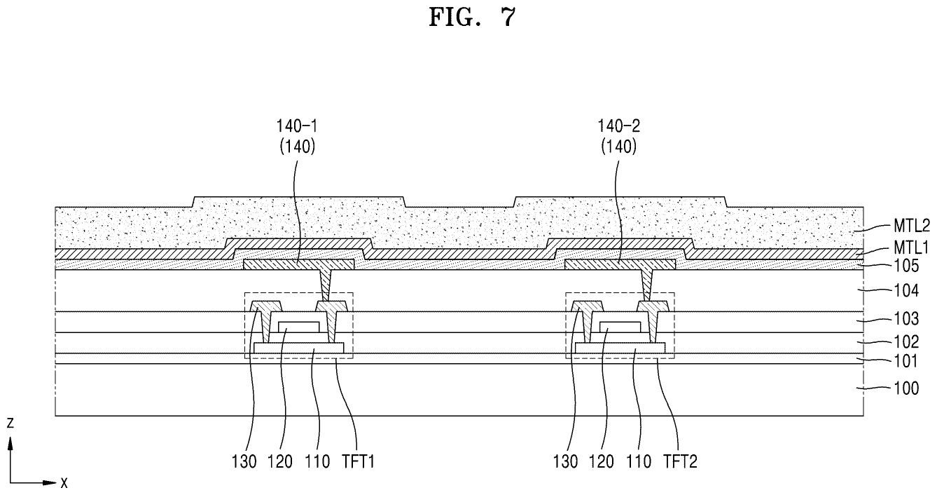

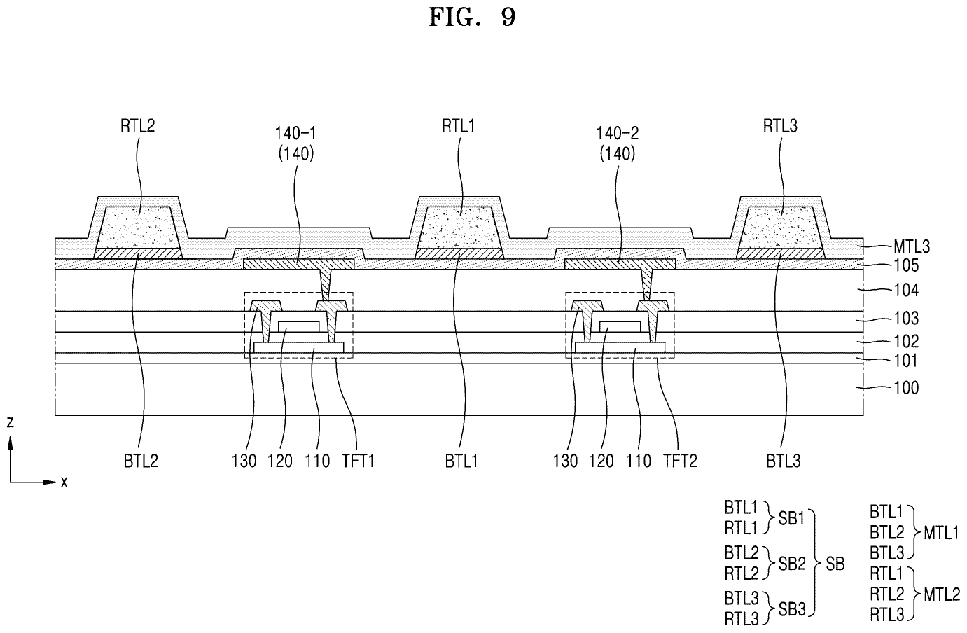

In an embodiment, the conductive structure STB may include a bottom layer BTL1, BTL2, BTL3 and protrusions PTL1, PTL2, PTL3. The bottom layer BTL1, BTL2, BTL3 may include a conductive material and may be disposed on the pixel defining layer 105 (e.g., disposed directly thereon in the z-axis direction). In an embodiment, the bottom layer BTL1, BTL2, BTL3 may be formed by performing an etching process on a first metal layer MTL1 of FIG. 7 to be described below. The protrusions PTL1, PTL2, PTL3 may include the same conductive material as included in the bottom layer BTL1, BTL2, BTL3 and may protrude upwards with reference to (e.g., with respect to) the pixel defining layer 105. In an embodiment, the protrusions PTL1, PTL2, PTL3 may be formed by performing an etching process on a third metal layer MTL3 of FIG. 9 to be described below.

One end of the protrusions PTL1, PTL2, PTL3 may directly contact an outer side surface of the bottom layer BTL1, BTL2, BTL3 and an upper surface of the pixel defining layer 105. Another end of the protrusions PTL1, PTL2, PTL3 may be a protrusion lip protruding towards an inner direction of the conductive structure STB. The bottom layer BTL1, BTL2, BTL3 and the protrusions may define a recess space of the conductive structure STB. For example, the protrusions PTL1, PTL2, PTL3 may protrude in approximately a z-axis direction or in a direction between the z-axis and x-axis with reference to (e.g., with respect to) the substrate 100. The protrusion lip, which is another end of the protrusions PTL1, PTL2, PTL3, may protrude in approximately an x-axis direction or in a direction parallel to the substrate 100.

For example, in an embodiment a first conductive structure STB1 may include a first protrusion PTL1-1, PTL1-2 and a first bottom layer BTL1. The first protrusion PTL1-1, PTL1-2 may include a 1-1st protrusion PTL1-1 close to the first emission region E1 and a 1-2nd protrusion PTL1-2 close to the second emission region E2 with reference to the first bottom layer BTL1. Another end (e.g., an upper end in the z-axis direction) of the 1-1st protrusion PTL1-1 may be a 1-1st protrusion lip PTT1-1, and another end (e.g., an upper end in the z-axis direction) of the 1-2nd protrusion PTL1-2 may be a 1-2nd protrusion lip PTT1-2.

The first intermediate layer 150-1 may cover the 1-1st protrusion PTL1-1 disposed close to the first emission region E1 among the first conductive structure STB1. For example, in an embodiment the first intermediate layer 150-1 may cover an upper surface and a side surface of the 1-1st protrusion lip PTT1-1 of the 1-1st protrusion PTL1-1 disposed close to the first emission region E1. The side surface of the 1-1st protrusion lip PTT1-1 may refer to a side surface facing the inside of the first conductive structure STB1 among side surfaces of the 1-1st protrusion lip PTT1-1. The first counter electrode 160-1 may cover the first intermediate layer 150-1 covering the upper surface of the 1-1st protrusion lip PTT1-1. The first counter electrode 160-1 may cover the first intermediate layer 150-1 covering the side surface of the 1-1st protrusion lip PTT1-1. For example, the first counter electrode 160-1 may directly contact the 1-1st protrusion lip PTT1-1. For example, the first counter electrode 160-1 may cover the upper surface and side surface of the first intermediate layer 150-1 and may extend to the side surface of the 1-1st protrusion lip PTT1-1. The first counter electrode 160-1 may terminate at an inner end of the side surface of the 1-1st protrusion lip PTT1-1. The first counter electrode 160-1 may directly contact a lower end of the side surface of the 1-1st protrusion lip PTT1-1. In an embodiment, the lower end of the side surface of the 1-1st protrusion lip PTT1-1 may be a point (e.g., region) not covered by the first intermediate layer 150-1.

The second intermediate layer 150-2 may cover the 1-2nd protrusion PTL1-2 disposed close to the second emission region E2 among the first conductive structure STB1. For example, in an embodiment the second intermediate layer 150-2 may cover an upper surface and a side surface of the 1-2nd protrusion lip PTT1-2 of the 1-2nd protrusion PTL1-2 disposed close to the second emission region E2. The side surface of the 1-2nd protrusion lip PTT1-2 may refer to a side surface facing the inside of the first conductive structure STB1 among side surfaces of the 1-2nd protrusion lip PTT1-2. The second counter electrode 160-2 may cover the second intermediate layer 150-2 covering the upper surface of the 1-2nd protrusion lip PTT1-2. The second counter electrode 160-2 may cover the second intermediate layer 150-2 covering the side surface of the 1-2nd protrusion lip PTT1-2. For example, the second counter electrode 160-2 may directly contact the 1-2nd protrusion lip PTT1-2. For example, the second counter electrode 160-2 may cover the upper surface and side surface of the second intermediate layer 150-2 and may extend to the side surface of the 1-2nd protrusion lip PTT1-2. The second counter electrode 160-2 may terminate at an inner end of the side surface of the 1-2nd protrusion lip PTT1-2. The second counter electrode 160-2 may directly contact a lower end of the side surface of the 1-2nd protrusion lip PTT1-2. In this embodiment, the lower end of the side surface of the 1-2nd protrusion lip PTT1-2 may be a point (e.g., a region) not covered by the second intermediate layer 150-2.

The thin film encapsulation layer TFE may seal the intermediate layer 150 and the counter electrode 160 on the substrate 100. As described above, the thin film encapsulation layer TFE may include the first encapsulation layer 310. In an embodiment, the first encapsulation layer 310 may include a 1-1st encapsulation layer 311 sealing the first intermediate layer 150-1 and the first counter electrode 160-1. The first encapsulation layer 310 may include a 1-2nd encapsulation layer 312 sealing the second intermediate layer 150-2 and the second counter electrode 160-2.

In an embodiment, the 1-1st encapsulation layer 311 may fill a portion of a recess space RSS1 of the first conductive structure STB1. For example, the 1-1st encapsulation layer 311 may fill a space around the 1-1st protrusion PTL1-1 in the recess space RSS1 of the first conductive structure STB1.

The 1-2nd encapsulation layer 312 may fill a portion of the recess space RSS1 of the first conductive structure STB1. For example, the 1-2nd encapsulation layer 312 may fill a space around the 1-2nd protrusion PTL1-2 in the recess space RSS1 of the first conductive structure STB1.

The 1-1st encapsulation layer 311 and the 1-2nd encapsulation layer 312 may be spaced apart from an upper surface of the first bottom layer BTL1. For example, in an embodiment the second encapsulation layer 320 may be disposed in a space between the 1-1st encapsulation layer 311 and the first bottom layer BTL1 (e.g., in the z-axis direction). The second encapsulation layer 320 may fill the space between the 1-1st encapsulation layer 311 and the first bottom layer BTL1 (e.g., in the z-axis direction). The third encapsulation layer 330 may be disposed on the second encapsulation layer 320 (e.g., disposed directly thereon in the z-axis direction).

Additionally, in the cross-sectional view, a second conductive structure STB2 may be disposed opposite to the first conductive structure STB1 with reference to the first emission region E1 (e.g., in the-x direction). In the cross-sectional view, a third conductive structure STB3 may be disposed opposite to the first conductive structure STB1 with reference to the second emission region E2 (e.g., in the x direction).

For convenience of description, while the conductive structures are separately described as the first conductive structure STB1 to the third conductive structure STB3 in the cross-sectional view, in the plan view, the first conductive structure STB1 to the third conductive structure STB3 may be one conductive structure STB. For example, in the specification, the conductive structure STB may be described as including the first conductive structure STB1 to the third conductive structure STB3.

For example, an upper surface and a side surface of a 2-1st protrusion lip PTT 2-1 may be covered by the first intermediate layer 150-1, and the first intermediate layer 150-1 may be covered by the first counter electrode 160-1. The first counter electrode 160-1 may directly contact a lower end of the side surface of the 2-1st protrusion lip PTT2-1. In the specification, the feature that the protrusion lip and the counter electrode directly contact each other may be understood to apply equally to other protrusion lips and counter electrodes.

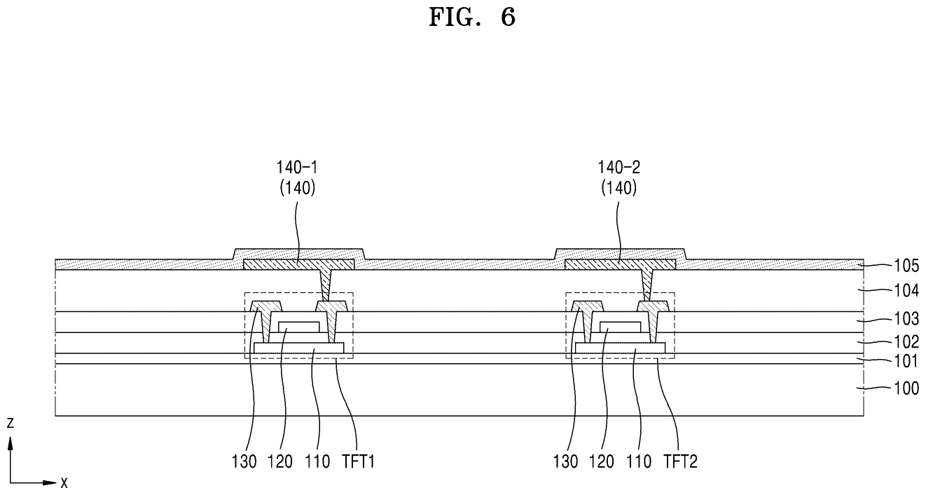

FIGS. 6 to 17 are cross-sectional views illustrating cross-sections of the display module according to the method for manufacturing the display module according to an embodiment.

For reference, among the descriptions of FIGS. 6 to 17, contents that are identical or overlapping with the above-described contents may be omitted.

As illustrated in FIG. 6, according to an embodiment, the method for manufacturing the display module 11 may include forming the first pixel electrode 140-1 and the second pixel electrode 140-2 disposed in a same layer as each other, and forming the pixel defining layer 105 on (e.g., directly thereon) the first pixel electrode 140-1 and the second pixel electrode 140-2.

The forming of the first pixel electrode 140-1 and the second pixel electrode 140-2 may include forming the buffer layer 101 on the substrate 100 (e.g., directly thereon in the z-axis direction), forming the semiconductor layer 110 on the buffer layer 101 (e.g., directly thereon in the z-axis direction), forming the gate insulating layer 102 on (e.g., directly thereon) the semiconductor layer 110, forming the gate layer 120 on the gate insulating layer 102, forming the interlayer insulating layer 103 on the gate layer 120 (e.g., directly thereon in the z-axis direction), forming the conductive layer 130 on the interlayer insulating layer 103 (e.g., directly thereon in the z-axis direction) to electrically connect the semiconductor layer 110 and the conductive layer 130 through the through hole, forming the organic insulating layer 104 on the conductive layer 130 (e.g., directly thereon in the z-axis direction), and forming the first pixel electrode 140-1 and the second pixel electrode 140-2 on (e.g., directly thereon) the organic insulating layer 104. The first pixel electrode 140-1 may be electrically connected to the first thin film transistor TFT1, and the second pixel electrode 140-2 may be electrically connected to the second thin film transistor TFT2.

The forming of the pixel defining layer 105 may include forming the pixel defining layer 105 on (e.g., directly thereon) the organic insulating layer 104 and the pixel electrodes 140. The pixel defining layer 105 may cover upper surfaces and side surfaces of the pixel electrodes 140 including the first pixel electrode 140-1 and the second pixel electrode 140-2, and may cover regions of the organic insulating layer 104 not covered by the pixel electrodes 140.

As illustrated in FIG. 7, according to an embodiment, the method for manufacturing the display module 11 may further include forming the first metal layer MTL1 on (e.g., directly thereon) the pixel defining layer 105 and forming the second metal layer MTL2 on (e.g., directly thereon) the first metal layer MTL1.

The first metal layer MTL1 may include a first conductive material. For example, in an embodiment the first metal layer MTL1 may include titanium (Ti). In an embodiment, the thickness (e.g., length in the z-axis direction) of the first metal layer MTL1 may be in a range of about 500 angstroms to about 2,000 angstroms.

The second metal layer MTL2 may include a second conductive material. For example, in an embodiment the second metal layer MTL2 may include aluminum (Al). In an embodiment, the thickness (e.g., length in the z-axis direction) of the second metal layer MTL2 may be in a range of about 4,000 angstroms to about 10,000 angstroms. An etching selectivity of the second conductive material may be greater than an etching selectivity of the first conductive material. For example, when applying an etching process with the same solution under the same conditions, the second conductive material may be more easily etched than the first conductive material.

By utilizing such a difference in etching selectivity between the first metal layer and the second metal layer, precise structure formation may be possible and manufacturing yield may be increased.

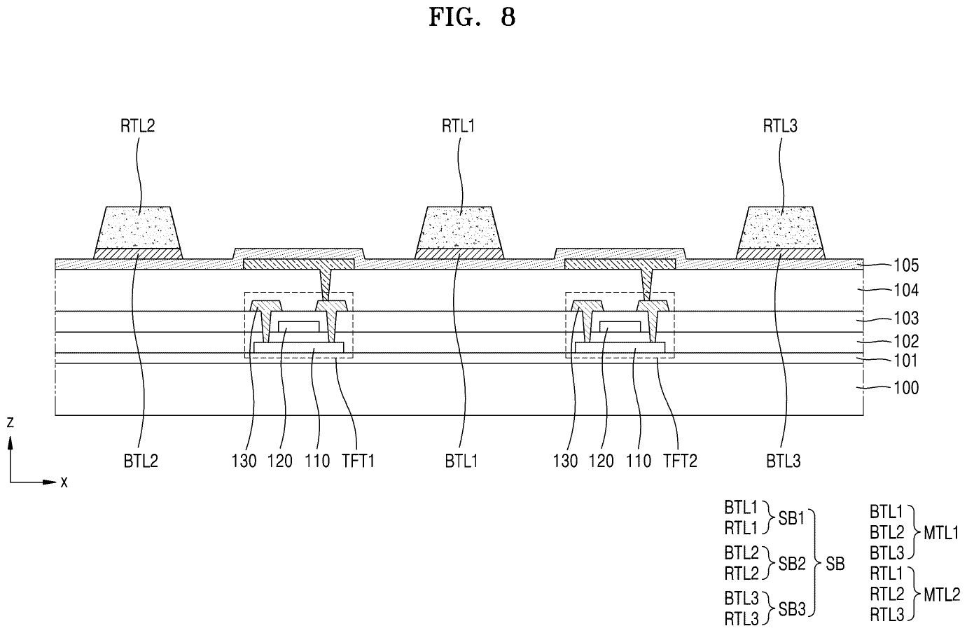

As illustrated in FIG. 8, according to an embodiment, the method for manufacturing the display module 11 may further include performing an etching process (e.g., a first etching process) on the first metal layer MTL1 and the second metal layer MTL2 to form initial conductive structures SB comprising the portion of the first metal layer MTL1 and the portion of the second metal layer MTL2.

When etching the first metal layer MTL1, the portion of the first metal layer MTL1 that becomes the bottom layer BTL1, BTL2, BTL3 of the initial conductive structures SB may be formed. When etching the second metal layer MTL2, the portion of the second metal layer MTL2 may be formed on (e.g., directly thereon) the bottom layer BTL1, BTL2, BTL3 of the initial conductive structures SB. The portion of the first metal layer MTL1 and a portion of the second metal layer MTL2 may form the initial conductive structures SB as shown in FIG. 8.

In an embodiment, in the cross-sectional view, the initial conductive structures SB may include a 1-1st structure SB1 disposed between the first pixel electrode 140-1 and the second pixel electrode 140-2 on the pixel defining layer 105. On the opposite side of the 1-1st structure SB1 with reference to the first pixel electrode 140-1, such as the lateral side in the-x direction, a 1-2nd structure SB2 may be disposed. On the opposite side of the 1-1st structure SB1 with reference to the second pixel electrode 140-2, such as the lateral side in the x direction, a 1-3rd structure SB3 may be disposed.

For example, in an embodiment the initial conductive structures SB may include the 1-1st structure SB1, the 1-2nd structure SB2, and the 1-3rd structure SB3. The structures disposed on both sides of the first pixel electrode 140-1 may be the 1-1st structure SB1 and the 1-2nd structure SB2. In the cross-sectional view, the first pixel electrode 140-1 and the 1-1st structure SB1 may be spaced apart in the x-axis direction, and the first pixel electrode 140-1 and the 1-2nd structure SB2 may be spaced apart in the-x-axis direction. The structures disposed on both sides (e.g., lateral sides) of the second pixel electrode 140-2 may be the 1-1st structure SB1 and the 1-3rd structure SB3. In the cross-sectional view as shown in FIG. 9, the second pixel electrode 140-2 and the 1-1st structure SB1 may be spaced apart in the-x-axis direction, and the second pixel electrode 140-2 and the 1-3rd structure SB3 may be spaced apart in the x-axis direction.

For example, in an embodiment the initial conductive structures SB may include two layers. In an embodiment, each of the initial conductive structures SB may include the portion of the first metal layer MTL1 as the bottom layer BTL1, BTL2, BTL3, and include the portion of the second metal layer MTL2 disposed on (e.g., disposed directly thereon in the z-axis direction) the bottom layer BTL1, BTL2, BTL3. An outer side surface of the portion of the first metal layer MTL1 and an outer side surface of the portion of the second metal layer MTL2 may form one surface. For example, the outer side surface of the portion of the first metal layer MTL1 and an outer side surface of the portion of the second metal layer MTL2 may be aligned with each other.

As a result of applying (e.g., performing) the etching process to the first metal layer MTL1 and the second metal layer MTL2, regions of the pixel defining layer 105 not covered by the initial conductive structures SB may be exposed upward. For example, upper surfaces of the pixel defining layer 105 between the initial conductive structures SB may be exposed. For example, the portion of the pixel defining layer 105 between the initial conductive structures SB may be exposed, and another portion of the pixel defining layer 105 may be covered by the initial conductive structures SB.

As illustrated in FIG. 9, according to an embodiment, the method for manufacturing the display module 11 may further include forming the third metal layer MTL3 covering upper surfaces and outer side surfaces of the initial conductive structures SB and the pixel defining layer 105 exposed between the initial conductive structures SB.

For example, in an embodiment the third metal layer MTL3 may include the same material as the first metal layer MTL1. For example, the third metal layer MTL3 may include the first conductive material. The third metal layer MTL3 may include titanium (Ti).

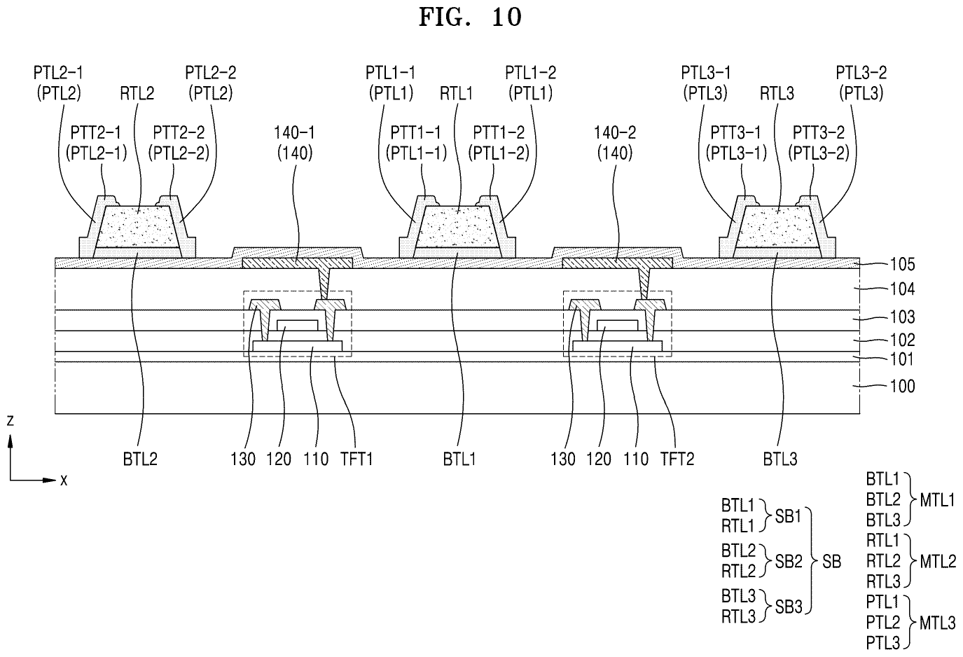

As illustrated in FIG. 10, according to an embodiment, the method for manufacturing the display module 11 may further include performing an etching process (e.g., a second etching process) on the third metal layer MTL3 to expose at least a central region of an upper surface of the portion of the second metal layer MTL2 upwardly.

Additionally, as the etching process is applied to (e.g., performed on) the third metal layer MTL3, the portion of the pixel defining layer 105 exposed between the initial conductive structures SB may be exposed upwardly. The remaining portion of the third metal layer MTL3 after etching becomes protrusions PTL1, PTL2, PTL3 to be described below, and the protrusions PTL1, PTL2, PTL3 may cover outer side surfaces of the initial conductive structures SB and edges of upper surfaces of the initial conductive structures SB. The protrusions PTL1, PTL2, PTL3 may cover regions around the initial conductive structures SB of the pixel defining layer 105. The protrusions PTL1, PTL2, PTL3 may not cover regions of the pixel defining layer 105 overlapping with the pixel electrodes 140. The protrusions PTL1, PTL2, PTL3 may not cover regions of the pixel defining layer 105 overlapping with the pixel electrodes 140 and their surrounding areas.

For example, one end (e.g., a first end that is a lower end) of the portion of the remaining third metal layer MTL3 after etching may directly contact an outer side surface of the portion of the first metal layer MTL1 and an upper surface of the pixel defining layer 105. Another end (e.g., a second end that is an upper end) of the portion of the remaining third metal layer MTL3 after etching may be the protrusion lip PTT1-1, PTT1-2 protruding towards an inner direction of the conductive structure STB.

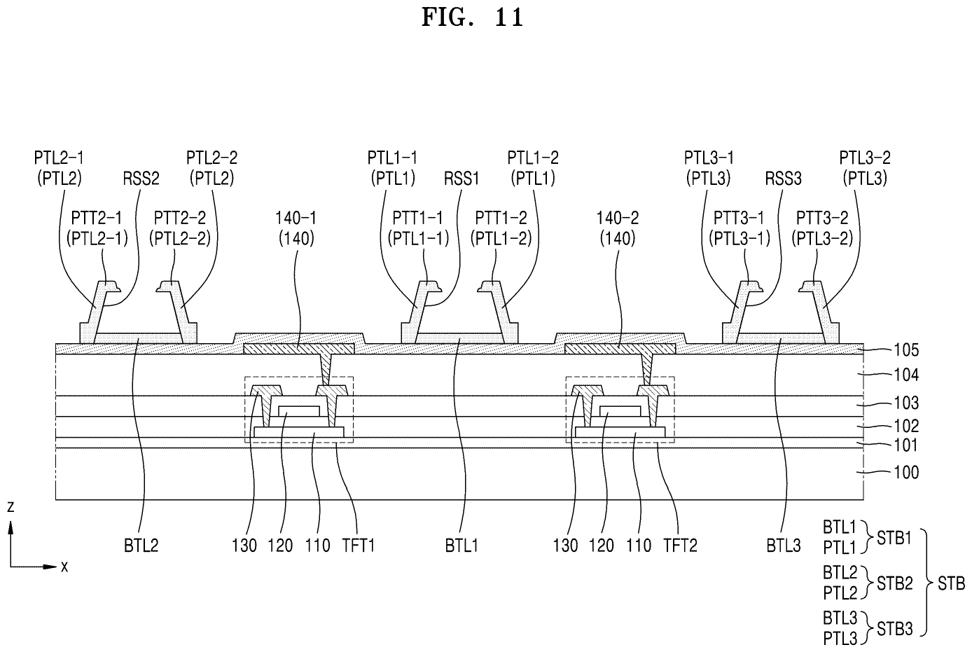

As illustrated in FIG. 11, according to an embodiment, the method for manufacturing the display module 11 may further include forming the conductive structure STB by removing the portion of the second metal layer MTL2 included in each of the initial conductive structures SB. In an embodiment, to remove the portion of the second metal layer MTL2 while maintaining the shapes of the first metal layer MTL1 and the third metal layer MTL3, an etching selectivity of the second conductive material of the second metal layer MTL2 may be greater than an etching selectivity of the first conductive material of the first metal layer MTL1 (or the third metal layer MTL3).

As a result of removing the portion of the second metal layer MTL2, the conductive structure STB may have a recess space RSS1 to RSS3 formed by removing the portion of the second metal layer MTL2. For example, the recess space RSS1 to RSS3 may be formed in a space where the portion of the second metal layer MTL2 was removed. The conductive structure STB may refer to the above-described conductive structure.

For example, the conductive structure STB, which is the above-described conductive structure, may include a portion of the first metal layer MTL1 as a bottom layer BTL1, BTL2, BTL3 comprising the first conductive material and disposed on the pixel defining layer 105 (e.g., disposed directly thereon in the z-axis direction). The conductive structure STB, which is the above-described conductive structure, may include a portion of the third metal layer MTL3 as protrusions PTL1, PTL2, PTL3 surrounding outer side surfaces of the bottom layer BTL1, BTL2, BTL3 and protruding upward in the cross-sectional view.

For example, one end (e.g., a lower end that is a first end) of a portion of the third metal layer MTL3 as protrusions PTL1, PTL2, PTL3 may directly contact an outer side surface of the bottom layer BTL1, BTL2, BTL3 and an upper surface of the pixel defining layer 105. For example, another end (e.g., a second end that is an upper end) of the portion of the third metal layer MTL3 may be protrusion lips PTT1-1 to PTT3-2 protruding towards an inner direction of the conductive structure STB.

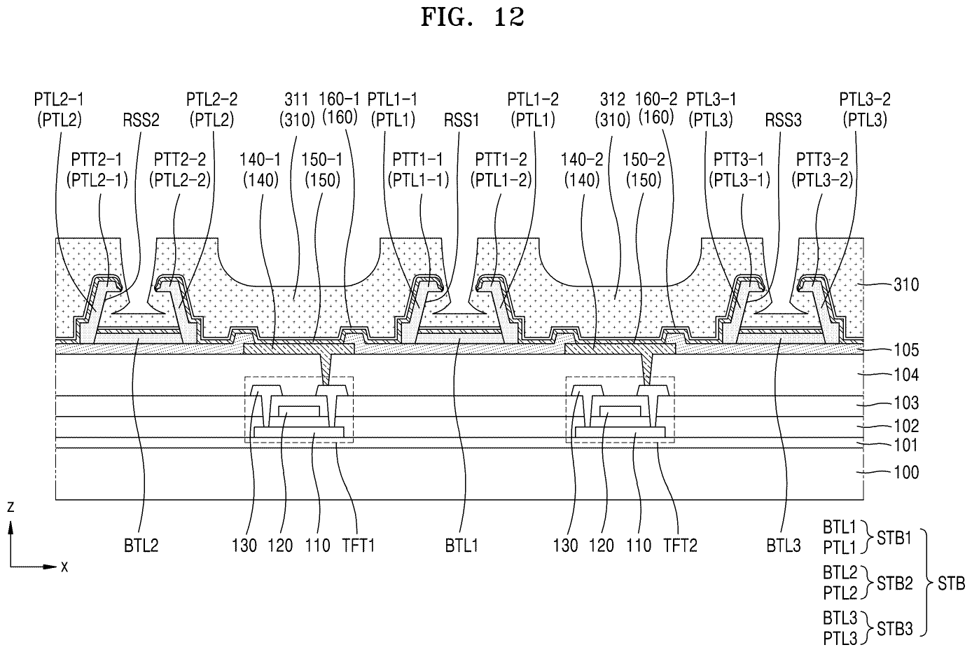

As illustrated in FIG. 12, according to an embodiment, the method for manufacturing the display module 11 may further include removing a portion of the pixel defining layer 105 not covered by the conductive structure STB to expose at least a central region of the first pixel electrode 140-1 and at least a central region of the second pixel electrode 140-2 upwardly. For example, a central portion of an upper surface of the first pixel electrode 140-1 and a central portion of an upper surface of the second electrode 140-2 may be exposed. At least the central region of the first pixel electrode 140-1 and at least the central region of the second pixel electrode 140-2 may refer to the above-described first emission region E1 and second emission region E2.

According to an embodiment, the method for manufacturing the display module 11 may further include forming a first intermediate layer 150-1 covering the conductive structures STB, at least the central region of the first pixel electrode 140-1, at least the central region of the second pixel electrode 140-2, and the pixel defining layer 105.

According to an embodiment, the method for manufacturing the display module 11 may further include forming a first counter electrode 160-1 covering the first intermediate layer 150-1 and directly contacting the conductive structure STB. For example, the first intermediate layer 150-1 may cover an upper surface and side surfaces of the protrusion lips PTL1, PTL2, and the first counter electrode 160-1 may directly contact a lower end of side surfaces of the protrusion lips PTT1-1, PTT2-2.

According to an embodiment, the method for manufacturing the display module 11 may further include forming a first encapsulation layer 310 on (e.g., directly thereon) the first counter electrode 160-1. An upper surface of the first encapsulation layer 310 may have a shape corresponding to the first counter electrode 160-1 and an upper surface of the conductive structure. As a result, the first encapsulation layer 310 may include grooves corresponding to spaces formed between the conductive structures and grooves corresponding to recess spaces inside the conductive structures. The first encapsulation layer 310 may seal the first intermediate layer 150-1 and the first counter electrode 160-1 on the first intermediate layer 150-1 between the conductive structures STB by covering portions of each of the conductive structures STB and the first emission region E1. The first encapsulation layer 310 may seal the first intermediate layer 150-1 and the first counter electrode 160-1 covering the upper surface and side surfaces of the conductive structure STB. The first encapsulation layer 310 may seal the first intermediate layer 150-1 and the first counter electrode 160-1 disposed on the upper surface of the bottom layer BTL1, BTL2, BTL3 of the conductive structure STB.

As illustrated in FIG. 12, the first intermediate layer 150-1 may be separated by the recess spaces RSS1, RSS2, RSS3 of the conductive structures STB. For example, the first intermediate layer 150-1 between the conductive structures STB (e.g., between the 2-1st structure STB1 and 2-2nd structure STB2) may extend in the x-axis direction to the upper surface of the 1-1st protrusion PTL1 -1 and the side surface of the 1-1st protrusion lip PTL1-1, but may be physically separated from the first intermediate layer 150-1 covering the upper surface of the first bottom layer BTL1 by the recess space RSS1. For example, the first intermediate layer 150-1 between the conductive structures STB (e.g., between the 2-1st structure and 2-2nd structure STB2) may extend in the -x-axis direction to the upper surface of the 2-2nd protrusion and the side surface of the 2-2nd protrusion lip PTT2-2, but may be physically separated from the first intermediate layer 150-1 covering the upper surface of the second bottom layer BTL2 by the recess space RSS2.

For example, the first counter electrode 160-1 between the conductive structures STB (e.g., between the 2-1st structure and 2-2nd structure STB2) may extend in the x-axis direction to the upper surface of the 1-1st protrusion and the side surface of the 1-1st protrusion lip PTT1-1, but may be physically separated from the first counter electrode 160-1 covering the upper surface of the second bottom layer BTL2 by the recess space RSS2. For example, the first counter electrode 160-1 between the conductive structures STB (e.g., between the 2-1st structure STB1 and 2-2nd structure STB2) may extend in the -x-axis direction to the upper surface of the 2-2nd protrusion PTL2-2 and the side surface of the 2-2nd protrusion lip PTT2-2, but may be physically separated from the first counter electrode 160-1 covering the upper surface of the second bottom layer by the recess space RSS2.

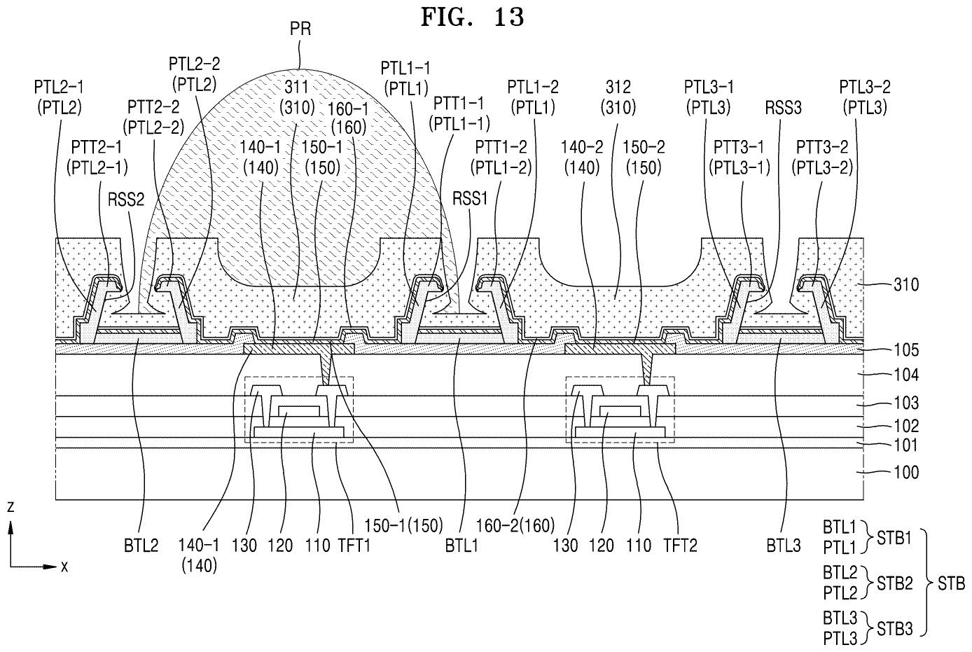

As illustrated in FIG. 13, according to an embodiment, the method for manufacturing the display module 11 may further include forming a photoresist PR covering the first intermediate layer 150-1 and the first counter electrode 160-1 between the 2-1st structure STB1 and the 2-2nd structure STB2, and covering the first intermediate layer 150-1 and the first counter electrode 160-1 on the 2-1st protrusion PTL 2-1 and the 2-2nd protrusion PTL 2-2. For example, the photoresist PR may fill portions of the recess spaces RSS1, RSS2 of each of the 2-1st structure STB1 and the 2-2nd structure STB2.

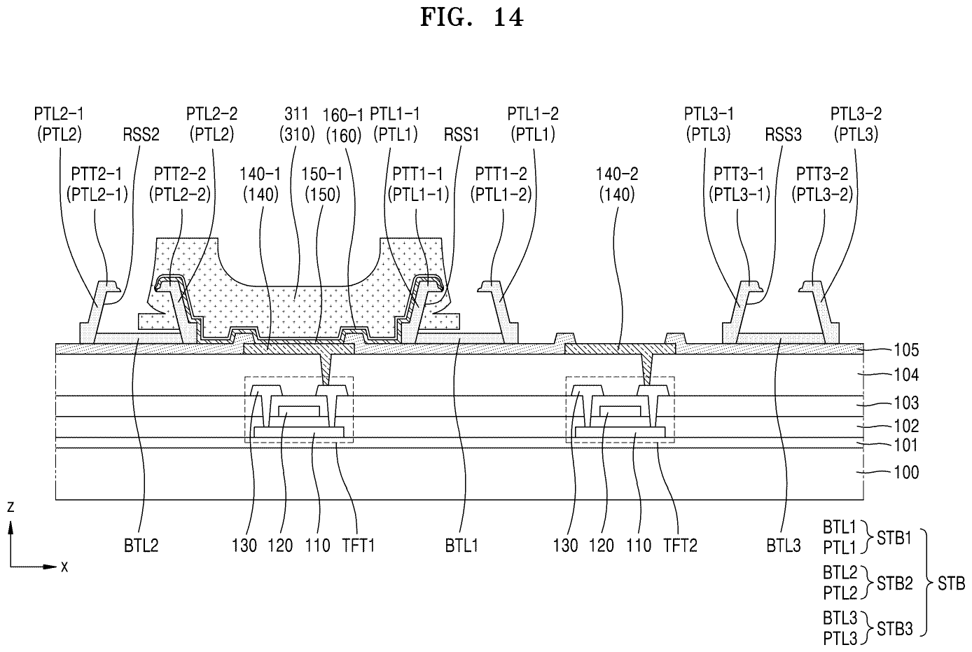

As illustrated in FIG. 14, according to an embodiment, the method for manufacturing the display module 11 may further include forming a 1-1st encapsulation layer 311 by removing portions of the first encapsulation layer 310 except portions covered by the photoresist PR.

According to an embodiment, the method for manufacturing the display module 11 may further include removing portions of the first counter electrode 160-1 not covered by the 1-1st encapsulation layer 311, and removing portions of the first intermediate layer 150-1 not covered by the 1-1st encapsulation layer 311 as well as portions of the first intermediate layer 150-1 and the first counter electrode 160-1 covered by the 1-1^{st} encapsulation layer 311 within the recess space RSS1. As a result, the bottom layer BTL1 of the 2-1st structure STB1 and the 1-1st encapsulation layer 311 may be spaced apart (e.g., in the z-axis direction) by the thickness of the first intermediate layer 150-1 and the first counter electrode 160-1, and an empty space corresponding to the thickness of the first intermediate layer 150-1 and the first counter electrode 160-1 may be formed between the bottom layer BTL1 of the 2-1st structure STB1 and the 1-1st encapsulation layer 311.

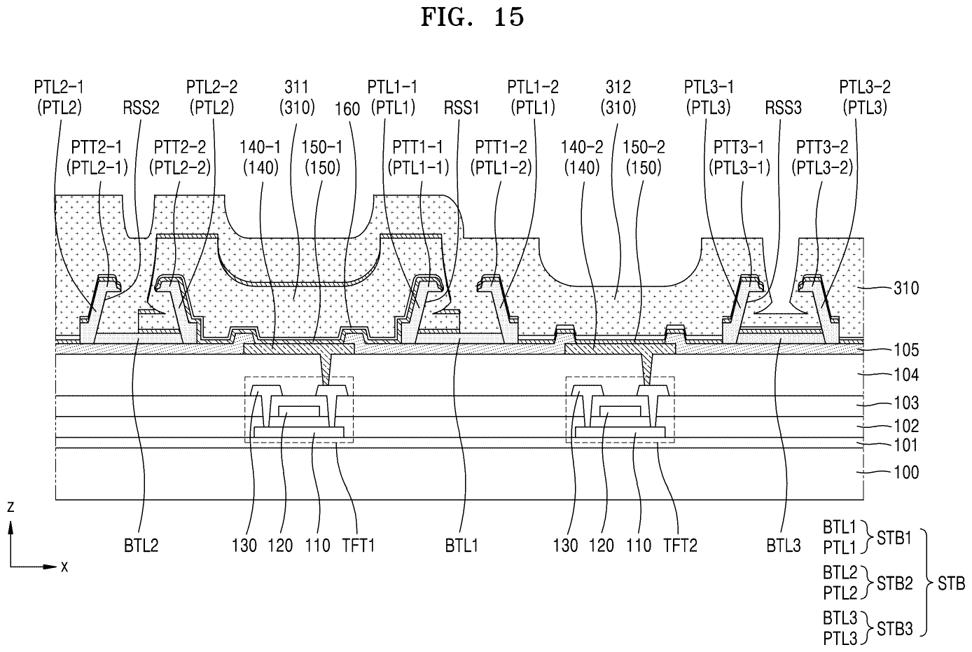

As illustrated in FIG. 15, according to an embodiment, the method for manufacturing the display module 11 may further include forming the second intermediate layer 150-2 on (e.g., directly thereon) the 1-1st encapsulation layer 311 and regions not covered by the 1-1st encapsulation layer 311, and forming the second counter electrode 160-2 on (e.g., directly thereon) the second intermediate layer 150-2.

According to an embodiment, the method for manufacturing the display module 11 may further include additionally forming the first encapsulation layer 310 on the second intermediate layer 150-2 and the second counter electrode 160-2. In an embodiment, the first encapsulation layer 310 may be a layer including the same material as the above-described 1-1st encapsulation layer 311 and may be a layer including the same material as the 1-2nd encapsulation layer 312 to be described below.

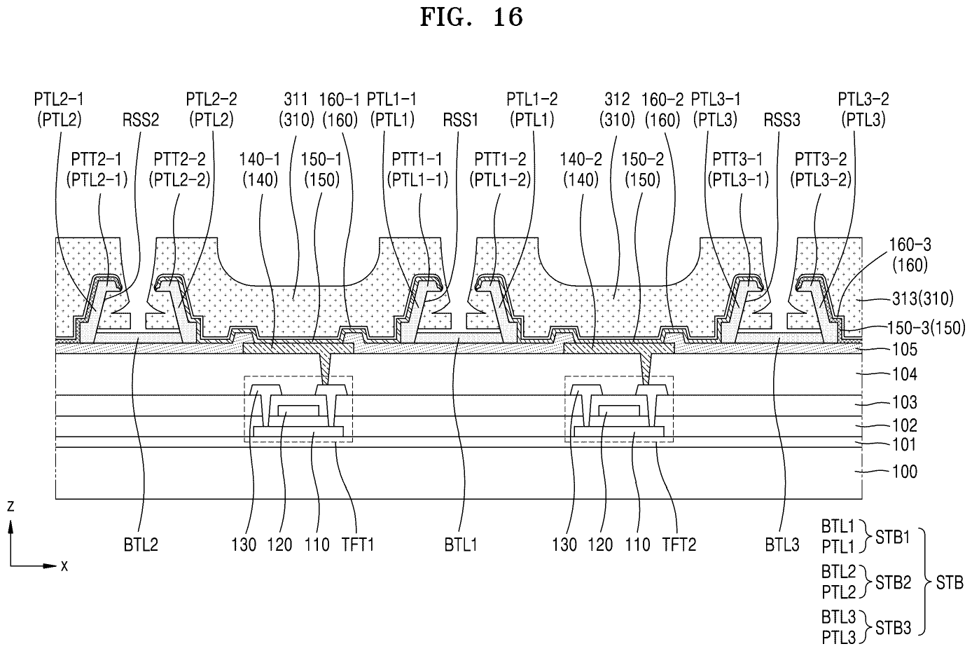

As illustrated in FIG. 16, according to an embodiment, the method for manufacturing the display module 11 may further include forming the 1-2nd encapsulation layer 312 by removing regions of the additionally formed first encapsulation layer 310 overlapping with the 1-1st encapsulation layer 311, and removing regions of the second intermediate layer 150-2 and the second counter electrode 160-2 overlapping with the 1-1st encapsulation layer 311.

The 1-2nd encapsulation layer 312 may seal the second intermediate layer 150-2 and the second counter electrode 160-2 by completely covering the second intermediate layer 150-2 and the second counter electrode 160-2. The 1-1st encapsulation layer 311 and the 1-2nd encapsulation layer 312 may be spaced apart in the x-axis direction in the recess space of the 2-1st structure. The 1-1st encapsulation layer 311 and the 1-2nd encapsulation layer 312 may be physically separated (e.g., in the x-axis direction) in the recess space RSS1 of the 2-1st structure STB1.

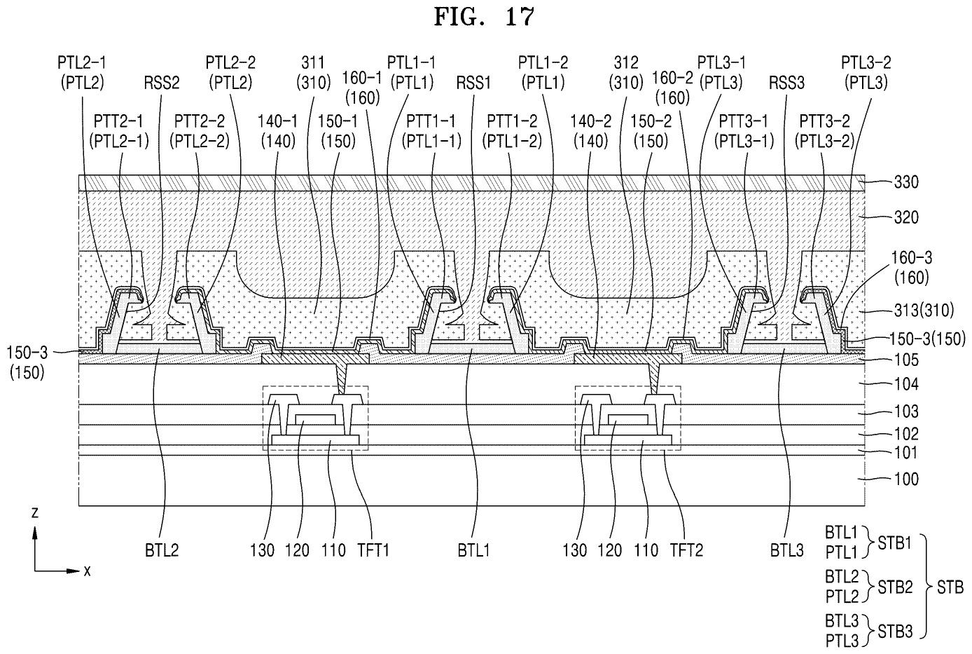

As illustrated in FIG. 17, according to an embodiment, the method for manufacturing the display module 11 may further include forming the 1-3rd encapsulation layer 313 in the same manner as forming the 1-2nd encapsulation layer 312. For example, according to an embodiment, the method for manufacturing the display module 11 may further include forming the third intermediate layer 150-3 on (e.g., directly thereon) the 1-1st encapsulation layer 311, the 1-2nd encapsulation layer 312, regions not covered by the 1-1st encapsulation layer 311, and regions not covered by the 1-2nd encapsulation layer 312, and forming the third counter electrode 160-3 on the third intermediate layer 150-3.

For example, according to an embodiment, the method for manufacturing the display module 11 may further include additionally forming the first encapsulation layer 310 on (e.g., directly thereon) the third intermediate layer 150-3 and the third counter electrode 160-3. The first encapsulation layer 310 may be a layer including the same material as the above-described 1-1st encapsulation layer 311 and 1-2nd encapsulation layer 312, and may be a layer including the same material as the 1-3rd encapsulation layer 313 to be described below.

For example, according to an embodiment, the method for manufacturing the display module 11 may further include forming the 1-3rd encapsulation layer 313 by removing regions of the additionally formed first encapsulation layer 310 overlapping with the 1-1st encapsulation layer 311 and the 1-2nd encapsulation layer 312, and removing regions of the third intermediate layer 150-3 and the third counter electrode 160-3 overlapping with the 1-1st encapsulation layer 311 and the 1-2nd encapsulation layer 312.

The 1-3rd encapsulation layer 313 may seal the third intermediate layer 150-3 and the third counter electrode 160-3 by completely covering the third intermediate layer 150-3 and the third counter electrode 160-3. The 1-2nd encapsulation layer 312 and the 1-3rd encapsulation layer 313 may be spaced apart in the x-axis direction in the recess space RSS3 of the 2-3rd structure STB3. The 1-2nd encapsulation layer 312 and the 1-3rd encapsulation layer 313 may be physically separated in the recess space RSS3 of the 2-3rd structure STB3.

Below, based on the above-described contents, a detailed description will be provided for an electronic device including a display module 11 according to an embodiment as follows.

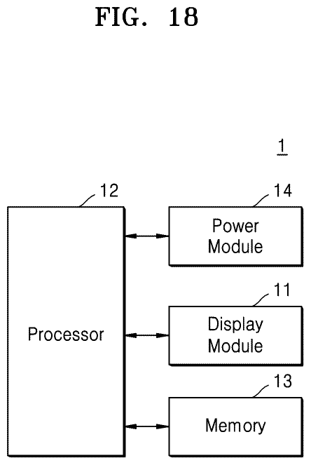

FIG. 18 is a block diagram of an electronic device according to an embodiment.

Referring to FIG. 18, according to an embodiment, an electronic device 1 may include the display module 11, a processor 12, a memory 13, and a power module 14.

The processor 12 may include at least one of a Central Processing Unit (CPU), an Application Processor (AP), a Graphics Processing Unit (GPU), a Communication Processor (CP), an Image Signal Processor (ISP), and a controller.

The memory 15 may store data information necessary for operation of the processor 12 or the display module 11. When the processor 12 executes an application stored in the memory 15, video data signals and/or input control signals may be transmitted to the display module 11, and the display module 11 may process the received signals to output video information through a display screen.

The power module 14 may include a power supply module such as a power adapter or a battery device, and a power conversion module that converts power supplied by the power supply module to generate power necessary for operation of the electronic device 1.

At least one of the components of the above-described electronic device 1 may be included in the display device according to the above-described embodiments. Additionally, among individual modules included within one module functionally, some may be included in the display device and others may be provided separately from the display device. For example, the display device may include the display module 11, and the processor 12, memory 13, and power module 14 may be provided in the form of other devices within the electronic device 1 that are not the display device.

The display module 11 of FIG. 18 may refer to one of the examples of the display module 11 described in FIGS. 1 to 17. While other descriptions are omitted for convenience of description, those skilled in the art may easily and clearly understand the display module 11 of FIG. 18 from the descriptions of FIGS. 1 to 17.

According to an embodiment, the electronic device 1 may include the memory 13 storing data information, the processor 12 generating data signals and/or control signals based on the data information, and the display module 11 operating based on the data signals and/or control signals. The display module 11 may include the substrate 100, the first pixel electrode 140-1 and the second pixel electrode 140-2 disposed on the substrate 100, the pixel defining layer 105 covering edges of each of the first pixel electrode 140-1 and the second pixel electrode 140-2 to define the first emission region E1 and the second emission region E2, and the conductive structure STB disposed between the first pixel electrode 140-1 and the second pixel electrode 140-2 on the pixel defining layer 105. The display module 11 may further include the first intermediate layer 150-1 covering the first emission region E1 and the portion of the conductive structure STB, the second intermediate layer 150-2 covering the second emission region E2 and the portion of the conductive structure STB, the first counter electrode 160-1 covering the first intermediate layer 150-1 and directly contacting the conductive structure STB, and the second counter electrode 160-2 covering the second intermediate layer 150-2 and directly contacting the conductive structure STB.

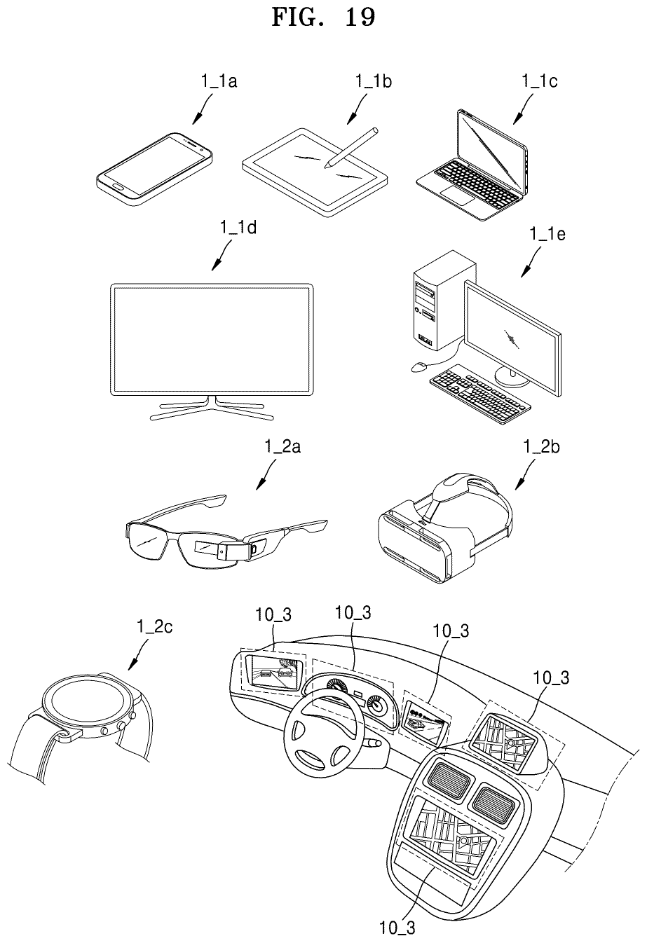

FIG. 19 is schematic views of electronic devices according to various embodiments.

Referring to FIG. 19, various electronic devices to which the display device according to embodiments of the present disclosure may be applied may include not only image display electronic devices such as smartphones 10_1a, tablet PCs 10_1b, laptops 10_1c, TVs 10_1d, and desktop monitors 10_1e, but also wearable electronic devices including display modules such as smart glasses 10_2a, head mounted displays 10_2b, and smart watches 10_2c, and vehicular electronic devices 10_3 including display modules such as instrument panels, center fascias, Center Information Displays (CID) disposed on dashboards, and room mirror displays of automobiles.

While non-limiting embodiments have been described with reference to the examples illustrated in the drawings, those skilled in the art will understand that various modifications and equivalent other embodiments are possible.

According to an embodiment configured as described above, the display module capable of reducing a defect rate, the method for manufacturing the same, and an electronic device may be implemented. Of course, the scope of the embodiments is not necessarily limited by such effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a display module, the method comprising:
forming a first pixel electrode and a second pixel electrode disposed on a same layer as each other on a substrate;
forming a pixel defining layer on the substrate and covering the first pixel electrode and the second pixel electrode;
forming a first metal layer on the pixel defining layer and a second metal layer on the first metal layer;
forming initial conductive structures comprising a portion of the first metal layer and a portion of the second metal layer by performing a first etching process on the first metal layer and the second metal layer, a portion of the pixel defining layer is exposed between the initial conductive structures by the first etching process;
forming a third metal layer covering upper surfaces and outer side surfaces of the initial conductive structures and the portion of the pixel defining layer exposed between the initial conductive structures; and
performing a second etching process on the third metal layer to expose, in an upward direction, at least a central region of an upper surface of the portion of the second metal layer.

2. The method of claim 1, further comprising forming a conductive structure by removing the portion of the second metal layer.

3. The method of claim 2, wherein:
the conductive structure has a recess space formed in a space where the portion of the second metal layer is removed.

4. The method of claim 2, wherein the conductive structure comprises:
a portion of the first metal layer as a bottom layer comprising a conductive material and disposed on the pixel defining layer; and
a portion of the third metal layer as a protrusion surrounding an outer side surface of the portion of the first metal layer and protruding upward in a cross-sectional view.

5. The method of claim 4, wherein:
the first metal layer and the third metal layer comprise a first conductive material; and
the second metal layer comprises a second conductive material,
wherein an etching selectivity of the second conductive material is greater than an etching selectivity of the first conductive material.

6. The method of claim 4, wherein:
a first end of the portion of the third metal layer directly contacts the outer side surface of the portion of the first metal layer and an upper surface of the pixel defining layer; and
a second end of the portion of the third metal layer is a protrusion lip protruding towards an inner direction of the conductive structure.

7. The method of claim 6, further comprising removing a portion of the pixel defining layer to expose, in an upward direction, at least a central region of the first pixel electrode and at least a central region of the second pixel electrode.

8. The method of claim 7, further comprising:
forming a first intermediate layer covering the conductive structure, at least the central region of the first pixel electrode, at least the central region of the second pixel electrode, and the pixel defining layer; and
forming a first counter electrode covering the first intermediate layer and directly contacting the conductive structure.

9. The method of claim 8, wherein:
the first intermediate layer covers an upper surface and a side surface of the protrusion lip, and the first counter electrode directly contacts a lower end of the side surface of the protrusion lip.

10. A display module comprising:
a substrate;
a first pixel electrode and a second pixel electrode disposed on the substrate;
a pixel defining layer disposed on the substrate and covering edges of each of the first pixel electrode and the second pixel electrode and exposing a central portion of upper surfaces of the first pixel electrode and the second pixel electrode to define a first emission region and a second emission region, respectively;
a conductive structure disposed between the first pixel electrode and the second pixel electrode on the pixel defining layer;
a first intermediate layer covering the first emission region and a first side of the conductive structure;
a second intermediate layer covering the second emission region and a second side of the conductive structure;
a first counter electrode covering the first intermediate layer and directly contacting the conductive structure; and
a second counter electrode covering the second intermediate layer and directly contacting the conductive structure.

11. The display module of claim 10, wherein:
the conductive structure comprises
a bottom layer comprising a conductive material and disposed on the pixel defining layer; and
a protrusion comprising the conductive material and protruding upwards with respect to the pixel defining layer.

12. The display module of claim 11, wherein:
a first end of the protrusion directly contacts an outer side surface of the bottom layer and an upper surface of the pixel defining layer; and
a second end of the protrusion is a protrusion lip protruding towards an inner direction of the conductive structure.

13. The display module of claim 12, wherein:
the first counter electrode directly contacts a side surface of the protrusion lip.

14. The display module of claim 12, wherein:
the first intermediate layer covers an upper surface and an inner side surface of the protrusion lip; and
the first counter electrode directly contacts a lower end of the inner side surface of the protrusion lip.

15. The display module of claim 12, wherein:
the bottom layer and the protrusion define a recess space of the conductive structure.

16. The display module of claim 15, further comprising:
the display module further comprises a first encapsulation layer sealing the first intermediate layer and the first counter electrode.

17. The display module of claim 16, wherein:
the first encapsulation layer fills a portion of the recess space.

18. The display module of claim 17, wherein:
the first encapsulation layer is spaced apart from an upper surface of the bottom layer.

19. The display module of claim 17, further comprising
a second encapsulation layer covering the first encapsulation layer and having a portion disposed between the first encapsulation layer and the bottom layer.

20. An electronic device comprising:
a memory storing data information;
a processor generating data signals and/or control signals based on the data information; and
a display module operating based on the data signals and/or control signals,
wherein the display module comprises:
a substrate;
a first pixel electrode and a second pixel electrode disposed on the substrate;
a pixel defining layer disposed on the substrate and covering edges of each of the first pixel electrode and the second pixel electrode and exposing a central portion of upper surfaces of the first pixel electrode and the second pixel electrode to define a first emission region and a second emission region, respectively;
a conductive structure disposed between the first pixel electrode and the second pixel electrode on the pixel defining layer;
a first intermediate layer covering the first emission region and a portion of the conductive structure;
a second intermediate layer covering the second emission region and a portion of the conductive structure;
a first counter electrode covering the first intermediate layer and directly contacting the conductive structure; and
a second counter electrode covering the second intermediate layer and directly contacting the conductive structure.
